(19) United States
(12) Patent Application Publication
(10) Pub. No.: US 2005/0020076 A1
(43) Pub. Date: Jan. 27, 2005

(54) Method for manufacturing MTJ cell of magnetic random access memory

(75) Inventors: Kye Nam Lee, Gyeonggi-do (KR); In Woo Jang, Seoul (KR); Sang Hyun Oh, Gyeonggi-do (KR); Young Ho Yang, Chungcheongbuk-do (KR); Jin Yong Seong, Seoul (KR); Suk Kyoung Hong, Gyeonggi-do (KR); Jin Gu Kim, Gyeonggi-do (KR)

Correspondence Address: HELLER EHRMAN WHITE & MCAULIFFE LLP, 1666 K STREET,NW, SUITE 300, WASHINGTON, DC, 20006, US

(73) Assignee: Hynix Semiconductor Inc., Gyeonggi-do (KR)

(21) Appl. No.: 10/734,226

(22) Filed: Dec. 15, 2003

(30) Foreign Application Priority Data
Jul. 21, 2003 (KR) 10-2003-0049687

(51) Int. Cl. H01L 21/302; H01L 21/461

(52) U.S. Cl. 438/689

(57) ABSTRACT

The present invention discloses a method for manufacturing MTJ cell of MRAM. In accordance with the method, a portion of a free magnetic layer by a hard mask layer pattern is subjected to a halo ion implant process. The state of the portion of the free magnetic layer subjected to the halo ion implant process is converted into an amorphous state. The portion of the free magnetic layer is then oxidized to form an oxide film. A patterning of MTJ cell is performed to form a MTJ cell, wherein polymers are not generated since the oxide film is etched instead of the free magnetic layer.

### BACKGROUND OF THE INVENTION

1. Field of the Invention

The present invention relates to a method for manufacturing MTJ cell of magnetic random access memory (abbreviated as ‘MRAM’), and in particular to an improved method for manufacturing MTJ cell of MRAM having a higher speed than an SRAM, integration density as high as a DRAM, and a property of a nonvolatile memory such as a flash memory.

2. Description of the Background Art

Most of the semiconductor memory manufacturing companies have developed the MRAM which uses a ferromagnetic material as one of the next generation memory devices.

The MRAM is a memory device for reading and writing information wherein multi-layer ferromagnetic thin films is used by sensing current variations according to a magnetization direction of the respective thin films. The MRAM has a high speed and low power consumption, and allows high integration density due to its unique properties of the magnetic thin film, and also performs a nonvolatile memory operation such as a flash memory.

The MRAM embodies a memory device by using a giant magneto resistive (GMR) or spin-polarized magneto-transmission (SPMT) phenomenon generated when the spin influences electron transmission.

The MRAM using the GMR phenomenon utilizes the fact that resistance remarkably varies when spin directions are different in two magnetic layers having a non-magnetic layer therebetween to implement a GMR magnetic memory device.

The MRAM using the SPMT phenomenon utilizes the fact that larger current transmission is generated when spin directions are identical in two magnetic layers having an insulating layer therebetween to implement a magnetic permeable junction memory device.

A transistor and a MTJ cell constitute a MRAM.

FIGS. 1a and 1b are cross-sectional views illustrating a conventional method for manufacturing a MTJ cell of a MRAM.

Referring to FIG. 1a, a device isolation film (not shown), a first word line (not shown) which serves as a read line, a transistor (not shown) having a source/drain region, a ground line (not shown), a conductive layer (not shown) and a second word line (not shown) which serves as a write line are formed on a semiconductor substrate (not shown). A lower insulating layer 11 planarizing the entire surface is then formed on the semiconductor substrate.

Thereafter, a metal layer 13 for connection layer connected to the conductive layer is formed on the lower insulating layer 11. The metal layer 13 comprises a metal selected from the group consisting of tungsten, aluminum, platinum, copper, iridium, ruthenium and combinations thereof.

Next, a stacked structure of a pinned magnetic layer 15, a tunneling barrier layer 17 and a free magnetic layer 19, namely a MTJ material layer, is formed on the metal layer 13. The pinned magnetic layer 15 and the free magnetic layer 19 comprise a magnetic material selected from the group consisting of Co, Fe, NiFe, CoFe, PtMn, IrMn and combinations thereof, respectively.

Thereafter, a hard mask layer 21 is formed on the free magnetic layer 19. A photoresist film pattern 23 is then formed on the free magnetic layer 19 via exposure and development process using a MTJ cell mask (not shown).

Now referring to FIG. 1b, the hard mask layer 21 and the free magnetic layer 19 are etched using the photoresist film pattern 23 as a mask. Corrosion occurs due to magnetic material having high oxidizing power generated during the etching process of the free magnetic layer 19, resulting in a electrical short between the free magnetic layer 19 and the pinned magnetic layer 15.

Moreover, a polymer 25, which is a non-volatile reaction by-product, is attached to the sidewall of the free magnetic layer 19 and the hard mask layer 21. A pinhole 27 is generated in the tunneling barrier layer 17 and the pinhole 27 may be filled by the polymer 25.

As described above, in accordance with the conventional method for manufacturing MTJ cell of MRAM, the magnetic material generated during the etching process of free magnetic layer corrodes the magnetic layers and a non-volatile reaction by-product such as polymer is attached to the sidewalls, resulting in an electrical short between the free magnetic layer and the pinned magnetic layer and overall degradation of characteristics of semiconductor device.

### SUMMARY OF THE INVENTION

Accordingly, it is an object of the present invention to provide a method for manufacturing MTJ cell of MRAM wherein a portion of the free magnetic layer to be etched is subjected to a halo ion implant process to be converted into an oxide film to prevent generation of the magnetic material having high oxidizing power and the polymer during the etching process of the free magnetic layer, thereby improving the characteristic and reliability of the device.

In order to achieve the above-described object of the invention, there is provided a method for manufacturing MTJ cell of magnetic random access memory (MRAM) comprising: forming a stacked structure of a pinned magnetic layer, an alumina layer and a free magnetic layer; forming a hard mask layer on the stacked structure; patterning the hard mask layer via photoetching process using a MTJ cell mask to form a hard mask layer pattern exposing a portion of the free magnetic layer; subjecting the exposed portion of the free magnetic layer to a halo ion implant process; oxidizing the exposed portion of the free magnetic layer; and patterning a MTJ cell by etching the stacked structure.

### BRIEF DESCRIPTION OF THE DRAWINGS

The present invention will become better understood with reference to the accompanying drawings which are given only by way of illustration and thus are not limitative of the present invention, wherein:

FIGS. 1a and 1b are cross-sectional views illustrating a conventional method for manufacturing a MTJ cell of a MRAM.

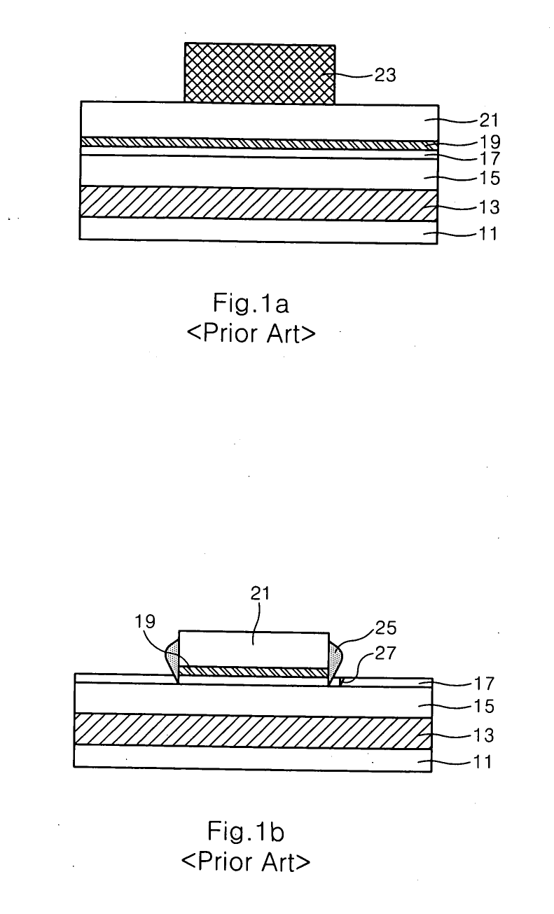

FIGS. 2a and 2b are cross-sectional views illustrating a method for manufacturing a MTJ cell of a MRAM in accordance with the present invention.

FIG. 3 is a graph showing magnetic characteristic of MTJ cell of the present invention wherein magnetic resistance according to electric field is shown.

### DETAILED DESCRIPTION OF THE PREFERRED EMBODIMENTS

A method for manufacturing MTJ cell of magnetic random access memory (MRAM) in accordance with a preferred embodiment of the present invention will now be described in detail with reference to the accompanying drawings.

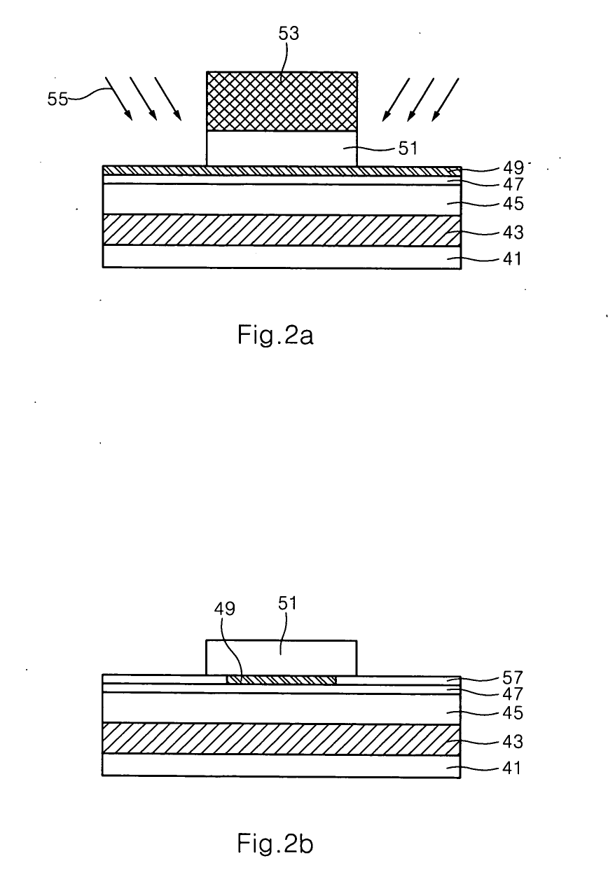

FIGS. 2a and 2b are cross-sectional views illustrating a method for manufacturing a MTJ cell of a MRAM in accordance with the present invention.

Referring to FIG. 2a, a device isolation film (not shown), a first word line (not shown) which serves as a read line, a transistor (not shown) having a source/drain region, a ground line (not shown), a conductive layer (not shown) and a second word line (not shown) which serves as a write line are formed on a semiconductor substrate (not shown). A lower insulating layer 41 planarizing the entire surface is then formed on the semiconductor substrate.

Thereafter, a metal layer 43 for connection layer connected to the conductive layer is formed on the lower insulating layer 41. Preferably, the metal layer 43 comprises a metal selected from the group consisting of tungsten, aluminum, platinum, copper, iridium, ruthenium and combinations thereof.

Next, a pinned magnetic layer 45 is formed on the metal layer 43. Preferably, the pinned magnetic layer 45 has a synthetic anti-ferromagnetic (“SAF”) structure and comprises a magnetic material selected from the group consisting of Co, Fe, NiFe, CoFe, PtMn, IrMn.

Thereafter, an alumina layer 47 which is a tunneling barrier layer is formed on the pinned magnetic layer 45. Preferably, the alumina layer 47 has a thickness ranging from 8 to 20 Å which is the minimum thickness required for data sensing. In one embodiment, the alumina layer 47 is formed by depositing an aluminum layer and then performing plasma discharge process in an O₃ gas atmosphere.

Next, a free magnetic layer 49 is formed on the alumina layer 47. The free magnetic layer 49 comprises the same material as the pinned magnetic layer 45.

Thereafter, a hard mask layer (not shown) is formed on the free magnetic layer 49. A photoresist film pattern 53 is then formed on the hard mask layer via exposure and development process using a MTJ cell mask (not shown). The hard mask layer 51 is then etched using the photoresist film pattern 53 as a mask to form a hard mask layer pattern 51 exposing a portion of the free magnetic layer 49 to be etched.

Next, the exposed portion of the free magnetic layer 49 is subjected to a halo ion implant process 55 using the photoresist film pattern 53 and the hard mask layer pattern 51 as a mask. The halo ion implant process 55 employs a gas molecule having a high molecular weight. The exposed portion of the free magnetic layer 49 is damaged by the gas molecule, and the state of the exposed portion is converted into an amorphous state. Preferably, the halo ion implant process 55 is performed with a tilt angle ranging from 0 to 90° wherein the semiconductor substrate is rotated so that the halo ion implant process is performed from four directions in order to prevent shadow phenomenon and excessive lower structure damages. The photoresist film pattern 23 is then removed.

Now referring to FIG. 2b, the exposed portion of the free magnetic layer 49 in amorphous state is oxidized via rapid thermal oxidation (“RTO”) process to form an oxide film 57. It is preferable that the RTO process oxidizes a portion of the free magnetic layer 49 under the hard mask layer pattern 51 in addition to the exposed portion of the free magnetic layer 49. The oxide film 57, alumina layer 47 and the pinned magnetic layer 45 are then etched using the hard mask layer as a mask to form a MTJ cell.

In the patterning process of the MTJ cell, the oxide film 57 is etched rather than the free magnetic layer 49 so that non-volatile reaction by-product due to etching of the free magnetic layer 49 is not generated and electrical short between the free magnetic layer 49 and the pinned magnetic layer 45 is prevented.

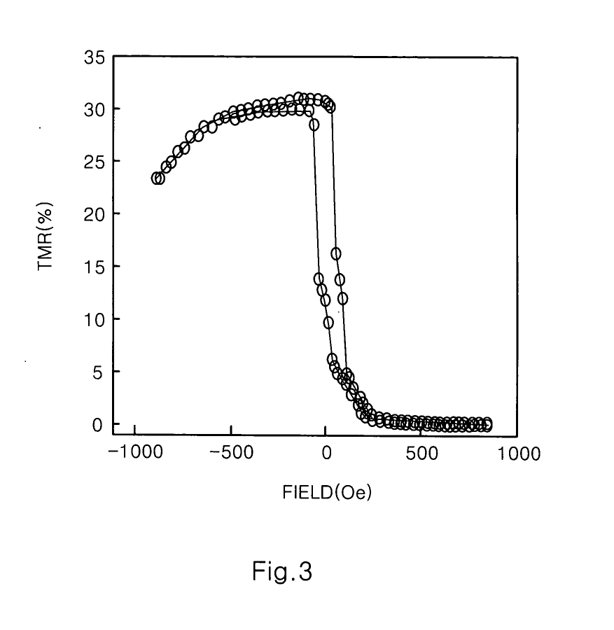

FIG. 3 is a graph showing magnetic characteristic of MTJ cell of the present invention wherein magnetic resistance according to electric field is shown.

As discussed earlier, in accordance with the present invention, a portion of the free magnetic layer to be etched is subjected to a halo ion implant process to prevent generation of polymer during the etching process of the free magnetic layer, thereby improving the characteristic and reliability of the device.

As the present invention may be embodied in several forms without departing from the spirit or essential characteristics thereof, it should also be understood that the above-described embodiment is not limited by any of the details of the foregoing description, unless otherwise specified, but rather should be construed broadly within its spirit and scope as defined in the appended claims, and therefore all changes and modifications that fall within the metes and bounds of the claims, or equivalences of such metes and bounds are therefore intended to be embraced by the appended claims.

1. A method for manufacturing MTJ cell of magnetic random access memory (MRAM) comprising:
forming a stacked structure of a pinned magnetic layer, an alumina layer and a free magnetic layer;
forming a hard mask layer on the stacked structure;
patterning the hard mask layer via a photoetching process using a MTJ cell mask to form a hard mask layer pattern exposing a portion of the free magnetic layer;
subjecting the exposed portion of the free magnetic layer to a halo ion implant process;
oxidizing the exposed portion of the free magnetic layer; and
patterning a MTJ cell by etching the stacked structure.

2. The method according to claim 1, wherein the halo ion implant process is performed in a manner that a tilt angle ranges from 0 to 90° and a ion is implanted from four directions.
